(19) United States
(12) Patent Application Publication
(10) Pub. No.: US 2016/0286672 A1
(43) Pub. Date: Sep. 29, 2016

(54) ENCLOSURE OF AN INDUSTRIAL APPARATUS

(71) Applicant: VIT, Saint-egreve (FR)

(72) Inventor: Christian WOLF, Saint - Egreve (FR)

(21) Appl. No.: 14/778,245

(22) PCT Filed: Mar. 26, 2014
(86) PCT No.: PCT/FR2014/050710

§ 371 Date: Sep. 18, 2015

(30) Foreign Application Priority Data
Mar. 28, 2013 (FR) 1352824

(51) Int. Cl. H05K 5/02; H05K 3/00; G01N 21/95; H05K 5/00

(52) U.S. Cl. CPC H05K 5/0226; H05K 5/0017; H05K 5/0239; H05K 3/00; G01N 21/95; G01N 2201/022

(57) ABSTRACT

An enclosure includes a door for accessing a space for receiving an industrial apparatus in which the door is hinged to a door frame supported by the enclosure by at least one connecting rod, the ends of which are hingedly respectively connected to the door frame and to the rear surface of the door, approximately at the middle of the length thereof

### BACKGROUND

The present disclosure generally relates to industrial installations and, more specifically, to chambers, packages, cabinets, or enclosures of industrial apparatuses. An example of application relates to in-line installations for processing, for example, electronic boards, comprising a succession of apparatuses for inspecting or for processing such boards.

### DISCUSSION OF THE RELATED ART

Enclosures housing industrial apparatuses are generally formed of a frame and of walls for enclosing the apparatus. For maintenance, inspection, or loading needs, such enclosures generally comprise an access door enabling an operator to open the enclosure.

The access doors are full or partial, that is, they enable or not the user to penetrate into the enclosure. In applications more particularly targeted by the present disclosure, the doors of access to the apparatus are partial, the operator remaining outside of the enclosure for maintenance operations.

More and more often, industrial apparatuses are equipped with control interfaces using a display or control screen. The operator generally needs to look up data, be it when the enclosure is closed or when the door is open. This compels to provide a display visible from the outside, door closed, as well as another display inside of the enclosure or inside of the door. This is expensive and inconvenient.

### SUMMARY

An object of an embodiment aims at providing a door of access to an internal space of an enclosure of an industrial apparatus, equipped with a display, which overcomes all or part of the disadvantages of usual chambers.

Another object of an embodiment aims at facilitating the access of an operator to a display or control screen equipping the door.

To achieve all or part of these and other objects, an enclosure comprising a door of access to a space for receiving an industrial apparatus is provided, wherein the door is hinged to a door frame supported by the enclosure by at least one connecting rod having its ends respectively hingedly connected to the door frame and to the rear surface of the door, approximately in the middle of the length thereof

According to an embodiment, one end of the connecting rod(s) is hinged to a vertical post of the door frame.

According to an embodiment, one end of the door is slidably assembled parallel to the door frame.

According to an embodiment, the sliding is horizontal.

According to an embodiment, a surface of the door, external in closed position, becomes functionally internal in open position.

According to an embodiment, an external surface of the door in closed position is, in open position, on the door frame side.

According to an embodiment, said door integrates a space for receiving a display.

According to an embodiment, the door frame comprises, in its upper or lower portion, a groove for receiving a pin fixed in the vicinity of one corner of the door, distal from the connecting rod(s).

According to an embodiment, the pin defines a rotation axis of the corner of the door, mobile in translation parallel to the door frame.

According to an embodiment, the enclosure further comprises ports for the passage of objects to be processed by the apparatus.

According to an embodiment, said door is assembled by means of at least two arms hinged on the one hand to the door frame and on the other hand to the rear surface of the door.

### BRIEF DESCRIPTION OF THE DRAWINGS

The foregoing and other features and advantages will be discussed in detail in the following non-limiting description of specific embodiments in connection with the accompanying drawings, among which:

FIG. 1 is a simplified partial front view of an enclosure for an industrial apparatus, equipped with an embodiment of a door;

FIG. 2 shows the enclosure of FIG. 1, with the door open;

FIGS. 3A, 3B, and 3C are simplified top views of the door of the enclosure of FIGS. 1 and 2, respectively in closed position, in an intermediate position, and in open position;

FIG. 4 is a simplified view of the back of the door in open position; and

FIG. 5 illustrates a detail of the door hinge mechanism.

### DETAILED DESCRIPTION

The same elements have been designated with the same reference numerals in the different drawings. For clarity, only those steps and elements which are useful to the understanding of the described embodiments have been shown and will be detailed. In particular, only the door and its mechanism have been illustrated, the embodiments which will be described being compatible with usual enclosures used for industrial apparatuses. Further, the nature of the apparatuses contained in the enclosure has not been detailed, the described embodiments being here again compatible with usual apparatuses.

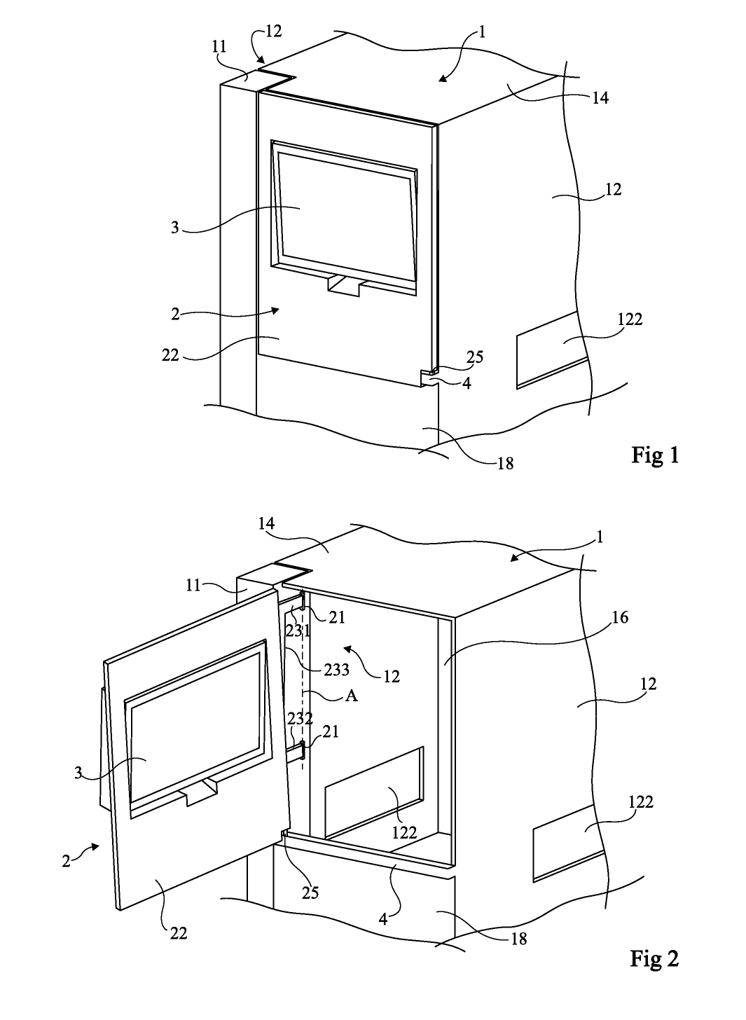

FIG. 1 is a front perspective view of an enclosure 1, intended to contain one or a plurality of industrial apparatuses (for example, an installation of optical inspection of electronic boards) and equipped with a door 2, illustrated as closed.

FIG. 2 is a perspective view of the enclosure of FIG. 1, with door 2 open.

Enclosure 1 comprises different walls, for example considering a cuboid chamber, lateral walls 12, an upper wall 14, possible a back wall 16 (FIG. 2), and most often a base (not shown in the drawings). According to the installation or the apparatus integrating enclosure 1, lateral walls 12 may be omitted if the apparatus is integrated in an in-line processing installation following other enclosures. As a variation, walls 12 comprise ports 122 or openings, intended for the transfer from one station to the other of the objects (for example, electronic boards) to be processed, without it being necessary to open the door to reload the enclosure with a new batch. Further, other shapes of enclosures may be envisaged according to the apparatuses that they are intended to house.

At front surface 18, enclosure 1 comprises a door 2 of access to the inner space. Door 2 is hinged on a door frame or frame of the enclosure. In the described embodiment, the presence of a vertical post 11 of a door frame belonging to a frame of the enclosure having door 2 hinged thereto is assumed.

Door 2 comprises, at external surface 22, a display screen 3 or another display device. In the example of FIGS. 1 and 2, display 3 is a flat display, preferably a touch screen to be used both as a display device and as a control member. As a variation, external surface 22 of door 2 comprises various display elements or control members, or even possibly no display. For example, it may be one or a plurality of series of pilot lamps indicative of the operation of the apparatus and one or a plurality of control members intended for the operation or the maintenance of the apparatus.

The hinging of door 2 to enclosure 1 is such that screen 3 is visible by an operator when the door is closed (FIG. 1) as well as when door 2 is open (FIG. 2) and the operator is working inside of the enclosure. In other words, surface 22 of the door, external in closed position, becomes functionally internal when the door is open.

This enables in particularly advantageous fashion a same display 3 to be easily accessible, be the enclosure open or closed, and to be in particular accessible when the operator is working in the internal space of the chamber.

Preferably, the right end of the door (in the orientation of the drawings) is slidably assembled in optional groove 4. For example, a pin 25, protruding from the lower end of the right-hand portion of door 2, slides in groove 4, the latter being parallel to the front of the enclosure. The presence of this sliding guiding suppresses a degree of liberty in the door motion and makes the operation thereof easier by forcing it to follow a given operating scheme.

In other words, the end of the door, opposite to vertical post 11 when the door is closed, is assembled to horizontally slide parallel to the door frame.

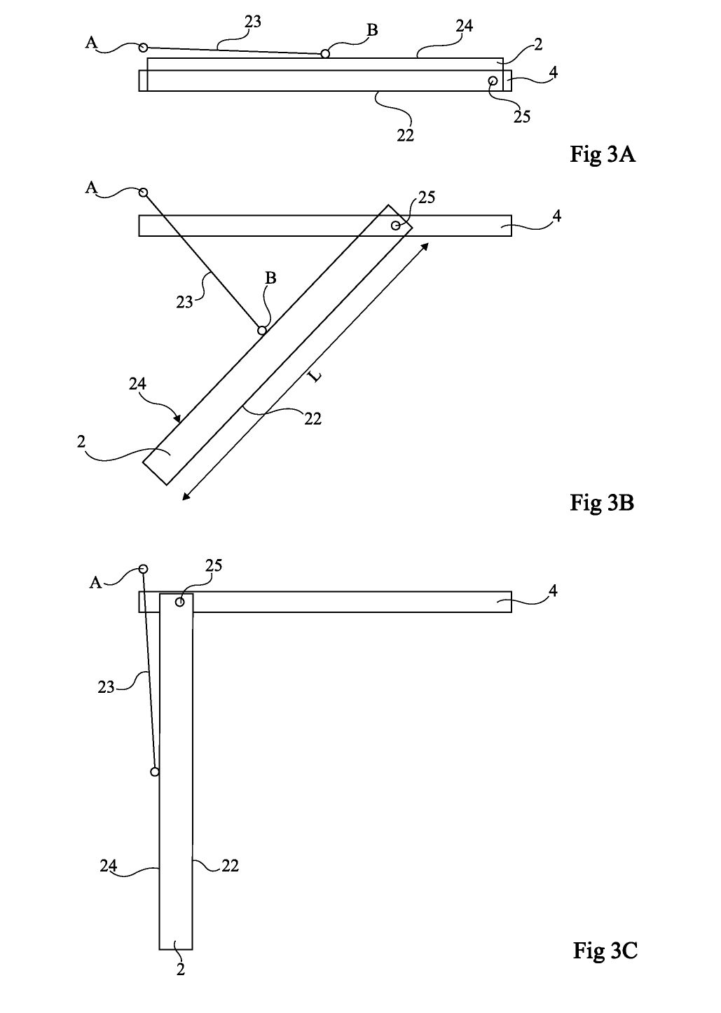

FIGS. 3A, 3B, and 3C are very simplified representations, in top view, of door 2 respectively in closed position, in an intermediate position, and in open position, illustrating the operating scheme relative to the door frame. In FIGS. 3A to 3C, the enclosure is not detailed but appears in the form of a hinge axis A, fixed with respect to the door frame, and of groove 4 for guiding the door in its lower portion. Axis A corresponds to the axis of one or a plurality of hinges 21 (FIG. 2) for hinging door 2 to enclosure 1.

The connection of the door panel to hinges 21 is performed via one or a plurality of connecting rods 23, hinged by one of their ends to axis A (hinges 21) and by their other respective ends at rear surface 24 of door 2. The position of hinge axis B of connecting rods 23 to door 2, along length L of the door, depends, among others, on the thickness thereof. Ideally, axis B is located in the middle of length L and, in practice, approximately in the middle, that is, more or less 10% away from this middle relative to length L. Pin 25 is located in or approximately in the lower right-hand corner (distal from the connecting rods) and defines an axis driven in translation in groove 4 parallel to the door frame.

The length of connecting rods 23 is at least equal to the half-length of door 2 to allow the disengaging thereof as illustrated in FIGS. 2 and 3C.

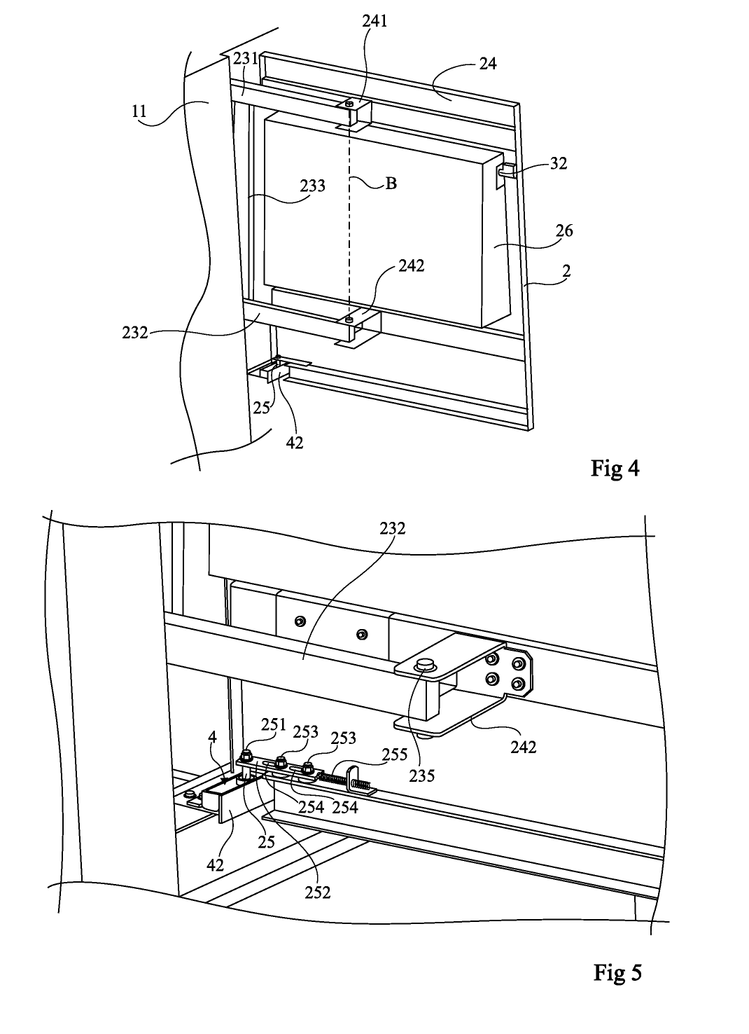

FIG. 4 is a perspective view of door 2 in open position seen from its rear surface 24.

FIG. 5 is an enlargement of the lower portion of the door illustrating the assembly of pin 25.

In the preferred embodiment of FIG. 4, the assembly of door 2 to door frame 11 via connecting rod mechanism 23 is performed by means of two respectively high and low horizontal arms 231 and 232 hinged at a first end, not shown in FIG. 4, to hinges 21 (FIG. 2) and at their other ends to stirrups 241 and 242 protruding from rear surface 24 of door 2. The hinging of arms (connecting rods) 231 and 232 to stirrups 241 and 242 as well as to hinges 21 is performed, for example, via dowels 235 or any other adapted means. For rigidity reasons, an approximately vertical bar 233 connects arms 231 and 232.

The function of stirrups 241 and 242 is, not only to hinge connecting rods 231 and 232, but also to space apart their hinging points (axis B) from rear surface 24. Such a spacing is optional but enables to shift the arms away from the thickness of the display housed in the door, especially if the door is curved.

In the example of FIG. 4, the display is housed in a protection casing 26. Preferably, display 3 (not shown in FIG. 4) can be inclined by being hinged to rear surface 24 of the door (hinging symbolized in FIG. 4 by a pin 32).

According to a preferred embodiment shown in FIG. 5 (not shown in FIG. 3C), pin 25 for guiding door 2 in groove 4 is connected to the door with a clearance allowing pin 25 to come out of the alignment of groove 4 when the door reaches the end of its travel in open position (position illustrated in FIGS. 4 and 5). To achieve this, upper portion 251 of pin 25 is attached to a plate 252 slidably assembled with respect to door 2. The sliding is ensured, for example, by ports 254 having slugs or rods 253 attached to door 2 sliding therein. At the end of the travel of the door to the open position, ports 253 enable to shift the door with respect to groove 4 towards the outside of the enclosure. Such a shifting of the door enables it to be in a position perpendicular to the front side of the enclosure as illustrated in FIG. 2, despite its thickness and with connecting rods 231 of fixed length. In practice, a spring 255 assists the motion of plate 252.

As a variation, particularly if the door is not curved, this function is fulfilled by the offset of stirrups 241 and 242.

As a variation, if this is made possible by the door thickness, connecting rods 231 which end up being parallel to the door in closed position may be provided. However, the assembly by means of pin 25 is a simpler embodiment.

The embodiments and their above-described variations considerably facilitate the use of the display and make it accessible, whatever the open or closed position of the door.

Another advantage induced by the provided operating scheme is that the connection cables between display 3 and the apparatus to which it should be connected (in practice, a computer tool) are always masked for the operator.

Various embodiments have been described, various alterations, modifications, and improvements will occur to those skilled in the art. In particular, although the embodiments have been described with a door having all its hinges on the left-hand side, these embodiments transpose to a door having its hinges on the right-hand side and with a clearance to the right. Further, although the presence of a groove 4 in the lower portion is a preferred embodiment, since it takes part in holding the door, such a groove may be located in the upper portion or two grooves may be provided. Further, the number of connecting rods 23 depends on the height of door 2 and on the required mechanical behavior. Finally, the practical implementation of the embodiments which have been described is within the abilities of those skilled in the art based on the functional indications given hereabove, taking into account the dimensions of the door and particularly its thickness which conditions, in particular, the position of axis B relative to the middle of the door.

1. An enclosure comprising a door of access to a space for receiving an industrial apparatus, wherein the door is hinged on a door frame supported by the enclosure by at least one connecting rod having its ends respectively hingedly connected to the door frame and to the rear surface of the door, approximately in the middle of the length thereof.

2. The enclosure of claim 1, wherein one end of the connecting rod(s) is hinged to a vertical post of the door frame.

3. The enclosure of claim 1, wherein one end of the door is slidably assembled parallel to the door frame.

4. The enclosure of claim 1, wherein the sliding is horizontal.

5. The enclosure of claim 1, wherein a surface of the door, external in closed position, becomes functionally internal in open position.

6. The enclosure of claim 1, wherein a surface of the door, external in closed position is, in open position, on the side of the door frame.

7. The enclosure of claim 1, wherein said door integrates a space for receiving a display.

8. The enclosure of claim 1, wherein the door frame comprises, in its upper or lower portion, a groove for receiving a pin fixed in the vicinity of one corner of the door, distal from the connecting rod(s).

9. The enclosure of claim 8, wherein the pin defines a rotation axis of the corner of the door, mobile in translation parallel to the door frame.

10. The enclosure of claim 1, further comprising ports for the passage of objects to be processed by the apparatus.

11. The enclosure of claim 1, wherein said door is assembled by means of at least two arms hinged on the one hand to the door frame and on the other hand to the rear surface of the door.
